(19) United States
(12) Patent Application Publication
(10) Pub. No.: US 2013/0032823 A1
(43) Pub. Date: Feb. 7, 2013

(54) SILICON CARBIDE SEMICONDUCTOR DEVICE

(71) Applicant: Hideki Hayashi, Osaka-shi (JP)

(72) Inventor: Hideki Hayashi, Osaka-shi (JP)

(73) Assignee: Sumitomo Electric Industries, Ltd., Osaka-shi (JP)

(21) Appl. No.: 13/565,209

(22) Filed: Aug. 2, 2012

Related U.S. Application Data
(60) Provisional application No. 61/515,587, filed on Aug. 5, 2011.

(30) Foreign Application Priority Data
Aug. 5, 2011 (JP) 2011-171565

(51) Int. Cl. H01L 29/161

(52) U.S. Cl. 257/77; 257/E29.084

(57) ABSTRACT

A first layer has a first conductivity type. A second layer is provided on the first layer such that a part of the first layer is exposed, and it has a second conductivity type. First to third impurity regions penetrate the second layer and reach the first layer. Each of the first and second impurity regions has the first conductivity type.

The third impurity region is arranged between the first and second impurity regions and it has the second conductivity type. First to third electrodes are provided on the first to third impurity regions, respectively. A Schottky electrode is provided on the part of the first layer and electrically connected to the first electrode.

### BACKGROUND OF THE INVENTION

1. Field of the Invention

This invention relates to a silicon carbide semiconductor device and particularly to a silicon carbide semiconductor device having a Schottky electrode.

2. Description of the Background Art

Some power semiconductor devices containing silicon carbide (SiC) have both of a function of a switching element and a function of a diode (rectifying element). For example, Japanese Patent Laying-Open No. 2009-259963 discloses a semiconductor device having a semiconductor substrate, a horizontal transistor, a back electrode, and a rectifying element structure. The horizontal transistor is formed on a front surface side of a semiconductor substrate and a current flows in a direction along the front surface of the semiconductor substrate between source and drain regions. The horizontal transistor includes a front electrode connected to any one of the source and drain regions. The back electrode is formed on a back surface side opposite to the front surface of the semiconductor substrate. A rectifying element is formed between the front electrode and the back electrode.

According to the technique described in Japanese Patent Laying-Open No. 2009-259963, the source and the drain of the horizontal transistor serving as the switching element are provided on the front surface side of the semiconductor substrate, while a Schottky electrode of a diode serving as the rectifying element is provided on the back surface side of the semiconductor substrate. Therefore, it has been difficult to connect the back electrode side of the diode to the switching element. Thus, it has also been difficult to obtain a semiconductor device having such a structure that a diode is connected as a free-wheeling diode between a source and a drain of a switching element.

### SUMMARY OF THE INVENTION

This invention was made to solve the problems as described above, and an object of this invention is to provide a silicon carbide semiconductor device having such a structure that a free-wheeling diode is connected between a source and a drain of a switching element with the use of a single silicon carbide substrate.

A silicon carbide semiconductor device according to one aspect of the present invention includes a silicon carbide substrate, first to third electrodes, and a Schottky electrode. The silicon carbide substrate includes first and second layers. The first layer has a first conductivity type. The second layer is provided on the first layer such that a part of the first layer is exposed, and it has a second conductivity type different from the first conductivity type. The silicon carbide substrate has first to third impurity regions penetrating the second layer and reaching the first layer. Each of the first and second impurity regions has the first conductivity type. The third impurity region is arranged between the first and second impurity regions and it has the second conductivity type. The first to third electrodes are provided on the first to third impurity regions, respectively. The Schottky electrode is provided on the part of the first layer and electrically connected to the first electrode.

According to this silicon carbide semiconductor device, a Schottky electrode is provided on the first layer, and a first electrode is provided on a first impurity region formed to reach this first layer. Thus, positional relation between the Schottky electrode and the first electrode is suited for electrical connection therebetween. Therefore, a semiconductor device having such a structure that a diode is connected as a free-wheeling diode between a source and a drain of a switching element can be obtained with the use of a single silicon carbide substrate.

Preferably, the first conductivity type is an n type. Thus, mobility of carriers can be enhanced.

Preferably, each of the first to third electrodes is an ohmic electrode. Thus, each of the first to third electrodes and the silicon carbide substrate can establish ohmic contact therebetween.

Preferably, the silicon carbide substrate includes a third layer sandwiching the first layer between the second layer and the third layer, having the second conductivity type, and electrically connected to the first electrode. Thus, electric field concentration within the first layer can be relaxed.

Preferably, the Schottky electrode is in contact with the first electrode Thus, the Schottky electrode and the first electrode can electrically be connected to each other without particularly providing an interconnection structure.

Preferably, the first layer has a first region in which the first to third impurity regions, the first to third electrodes, and the Schottky electrode are provided and a second region electrically isolated from the first region. Thus, an element separate from an element formed in the first region can be formed in the second region.

A silicon carbide semiconductor device according to another aspect of the present invention includes a silicon carbide substrate, first to sixth electrodes, a gate insulating film, and a Schottky electrode. The silicon carbide substrate includes first and second layers. The first layer has a first conductivity type. The second layer is provided on the first layer such that a part of the first layer is exposed, and it has a second conductivity type different from the first conductivity type. The silicon carbide substrate has first to fifth impurity regions. Each of the first, second, fourth, and fifth impurity regions has the first conductivity type and the third impurity region has the second conductivity type. Each of the first to third impurity regions penetrates the second layer and reaches the first layer. The third impurity region is arranged between the first and second impurity regions. Each of the fourth and fifth impurity regions is provided in the second layer. The first to fifth electrodes are provided on the first to fifth impurity regions, respectively. The first and fifth electrodes are electrically connected to each other, and the third and fourth electrodes are electrically connected to each other. The gate insulating film covers a portion between the fourth and fifth impurity regions, on the second layer. The sixth electrode is provided on the gate insulating film. The Schottky electrode is provided on the aforementioned part and electrically connected to the fourth electrode.

According to this silicon carbide semiconductor device, conduction between terminals implemented by the third and fourth electrodes and a terminal implemented by the second electrode can be switched by a potential of the sixth electrode. This switching operation has both of an advantage of a junction transistor and an advantage of an insulated gate transistor as a result of coordinated channel control making use of a depletion layer of a pn junction formed by the first layer and the third impurity region and channel control making use of an insulated gate on the second layer. Specifically, similarly to the junction transistor, a high-speed operation is enabled and an ON resistance is low. In addition, similarly to the insulated gate transistor, a normally-off characteristic can readily be obtained. Further, a semiconductor device having such a structure that a diode is connected as a free-wheeling diode between a source and a drain of a switching element can be obtained with the use of a single silicon carbide substrate.

As described above, according to the present invention, a semiconductor device having such a structure that a diode is connected as a free-wheeling diode between a source and a drain of a switching element can be obtained with the use of a single silicon carbide substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view schematically showing a configuration of a silicon carbide semiconductor device in a first embodiment of the present invention.

FIG. 2 is a diagram schematically showing an equivalent circuit of the silicon carbide semiconductor device in FIG. 1.

FIG. 3 is a plan view schematically showing a configuration of a silicon carbide semiconductor device in a second embodiment of the present invention.

FIG. 4 is a cross-sectional view schematically showing a configuration of a silicon carbide semiconductor device in a third embodiment of the present invention.

FIG. 5 is a diagram schematically showing an equivalent circuit of the silicon carbide semiconductor device in FIG. 4.

FIG. 6 is a cross-sectional view schematically showing a variation of FIG. 4.

FIG. 7 is a cross-sectional view schematically showing a configuration of a silicon carbide semiconductor device in a fourth embodiment of the present invention.

FIG. 8 is a diagram schematically showing an equivalent circuit of the silicon carbide semiconductor device in FIG. 7.

FIG. 9 is a cross-sectional view schematically showing a first step in a method of manufacturing the silicon carbide semiconductor device in FIG. 7.

FIG. 10 is a cross-sectional view schematically showing a second step in the method of manufacturing the silicon carbide semiconductor device in FIG. 7.

FIG. 11 is a cross-sectional view schematically showing a third step in the method of manufacturing the silicon carbide semiconductor device in FIG. 7.

FIG. 12 is a cross-sectional view schematically showing a fourth step in the method of manufacturing the silicon carbide semiconductor device in FIG. 7.

FIG. 13 is a cross-sectional view schematically showing a fifth step in the method of manufacturing the silicon carbide semiconductor device in FIG. 7.

FIG. 14 is a plan view schematically showing a configuration of a silicon carbide semiconductor device in a fifth embodiment of the present invention.

FIG. 15 is a cross-sectional view schematically showing a configuration of a silicon carbide semiconductor device in a sixth embodiment of the present invention.

### DESCRIPTION OF THE PREFERRED EMBODIMENTS

An embodiment of the present invention will be described hereinafter with reference to the drawings.

### First Embodiment

As shown in FIG. 1, a power module (silicon carbide semiconductor device) 51 in the present embodiment has an epitaxial substrate 30, a first electrode S1, a second electrode D1, a third electrode G1, a Schottky electrode SK, and an interlayer insulating film I1. Epitaxial substrate 30 is made of SiC, and it has a single crystal substrate 31, a buffer layer 32, a lower p layer 33 (third layer), an n layer 34 (first layer), and an upper p layer 35 (second layer). Buffer layer 32 is provided on single crystal substrate 31. Lower p layer 33 is provided on buffer layer 32. N layer 34 is provided on lower p layer 33. Upper p layer 35 is provided on n layer 34. Therefore, in a direction of thickness, upper p layer 35 and lower p layer 33 sandwich n layer 34. N layer 34 has an n type (a first conductivity type). Upper p layer 35 is provided on n layer 34 such that a part of n layer 34 is exposed. Each of upper p layer 35 and lower p layer 33 has a p type (a second conductivity type different from the first conductivity type).

First to third impurity regions 11 to 13 are provided in an upper surface (one surface) of epitaxial substrate 30. Each of first to third impurity regions 11 to 13 penetrates upper p layer 35 from the upper surface of epitaxial substrate 30 in the direction of thickness (a vertical direction in FIG. 1) and reaches n layer 34. Each of first and second impurity regions 11, 12 has the n type. Third impurity region 13 is arranged between first and second impurity regions 11, 12 and it has the p type.

First to third electrodes S1, D1, G1 are provided on first to third impurity regions 11 to 13, respectively. Each of first to third electrodes S1, D1, G1 is an ohmic electrode.

Schottky electrode SK is provided on the part of n layer 34. Schottky electrode SK is electrically connected to first electrode S1.

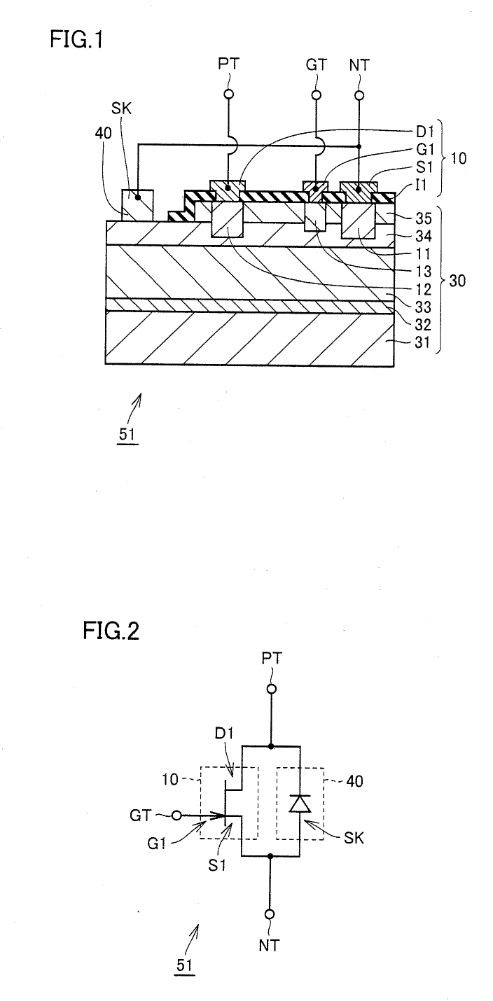

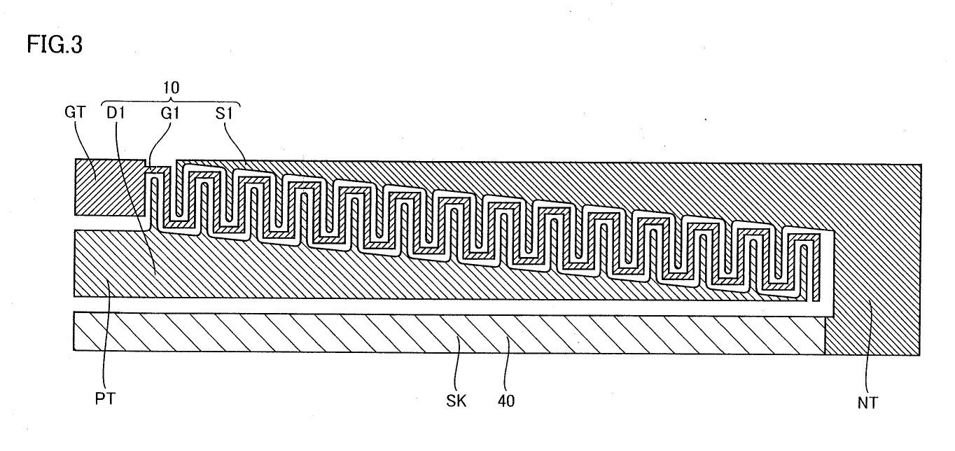

An equivalent circuit (FIG. 2) of power module 51 has a pair of main terminals NT and PT and a control terminal GT for external connection, and has a JFET portion 10 and a diode portion 40 as its internal structure. Specifically, third electrode G1 corresponds to control terminal GT. In addition, a portion where first electrode S1 and Schottky electrode SK are electrically connected to each other corresponds to main terminal NT. Further, second electrode D1 corresponds to main terminal PT. Furthermore, Schottky electrode SK corresponds to an anode of diode portion 40 and n layer 34 in contact with Schottky electrode SK in the vicinity of second electrode D1 corresponds to a cathode of diode portion 40.

Electrical connection between first electrode S1 and Schottky electrode SK corresponds to connection of the source of JFET portion 10 to the anode of diode portion 40. In addition, contact of n layer 34 with Schottky electrode SK in the vicinity of second electrode D1 corresponds to connection of the drain of JFET portion 10 to the cathode of diode portion 40. Namely, diode portion 40 is connected to JFET portion 10 so as to function as a free-wheeling diode.

Interlayer insulating film I1 is provided on the upper surface of epitaxial substrate 30 and it has an opening through which each of first to third electrodes S1, D1, G1 passes. Thus, each of first electrode S1 and second electrode D1 is provided on epitaxial substrate 30 within the opening in interlayer insulating film I1. Interlayer insulating film I1 covers a side surface (a left side surface in FIG. 1) of upper p layer 35, which faces Schottky electrode SK.

According to power module 51 in the present embodiment, first electrode S1 is provided on first impurity region 11 formed to reach n layer 34 where Schottky electrode SK is provided. Thus, positional relation between Schottky electrode SK and first electrode Si is suited to electrical connection therebetween. Specifically, as Schottky electrode SK and first electrode Si are both arranged on the upper surface of epitaxial substrate 30, they can readily electrically be connected to each other. Therefore, a power module having such a structure that a diode is connected as a free-wheeling diode between the source and the drain of JFET portion 10 (FIG. 2) can be obtained.

In addition, since JFET portion 10 and diode portion 40 (FIG. 2) are implemented with the use of a single epitaxial substrate 30, power module 51 can be obtained with the use of a single semiconductor chip.

Moreover, each of first to third electrodes S1, D1, G1 is an ohmic electrode. Thus, each of first to third electrodes S1, D1, G1 and epitaxial substrate 30 can establish ohmic contact therebetween.

Further, interlayer insulating film I1 covers the side surface of upper p layer 35, which faces Schottky electrode SK. Thus, contact between Schottky electrode SK and upper p layer 35 can be prevented.

### Second Embodiment

In the present embodiment, a two-dimensional layout of first to third electrodes S1, D1, G1 and Schottky electrode SK will particularly be described.

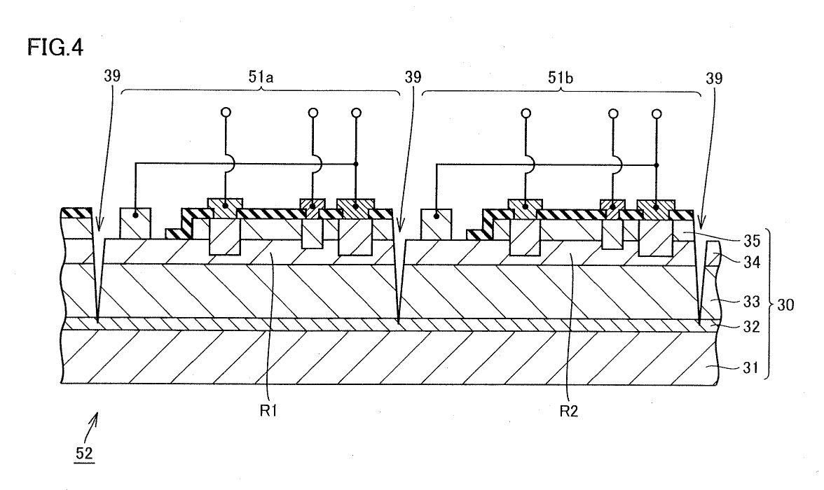

As shown in FIG. 3, main terminal NT, main terminal PT, and control terminal GT correspond to first electrode S1, second electrode D1, and third electrode G1, respectively. In the plan view (FIG. 3), Schottky electrode SK is in contact with first electrode S1. Thus, Schottky electrode SK and first electrode S1 can electrically be connected to each other without particularly providing an interconnection structure.

Since the configuration other than the above is substantially the same as the configuration in the first embodiment described above, the same or corresponding elements have the same reference characters allotted and description thereof will not be repeated.

### Third Embodiment

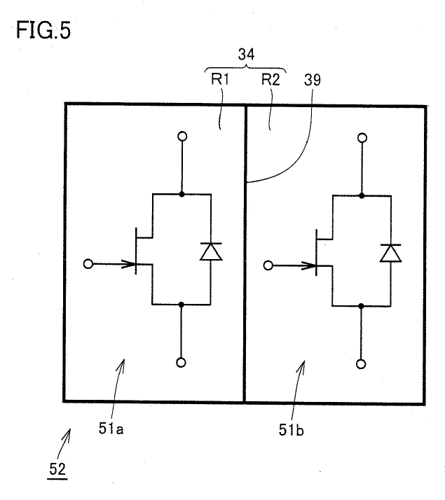

As shown in FIGS. 4 and 5, a power module (silicon carbide semiconductor device) 52 in the present embodiment has units (elements) 51a and 51b. Each of units 51a and 51b is substantially the same in configuration as power module 51 in the first embodiment (FIG. 1) or the second embodiment (FIG. 3) described above. Units 51a and 51b share a single epitaxial substrate 30. A groove portion 39 surrounding each of units 51a and 51b is provided on the upper surface side of epitaxial substrate 30. Groove portion 39 penetrates upper p layer 35 and n layer 34. Thus, n layer 34 has a region R1 (a first region) and a region R2 (a second region) electrically isolated from each other by groove portion 39. Regions R1 and R2 implement units 51a and 51b, respectively.

According to the present embodiment, units 51a and 51g having a set of a switching element and a free-wheeling diode are provided in regions R1 and R2, respectively. Thus, a power module having a plurality of sets of a switching element and a free-wheeling diode is obtained.

Though two units 51a and 51b are provided in the present embodiment, any number of units may be provided, and for example, 6 units may be provided.

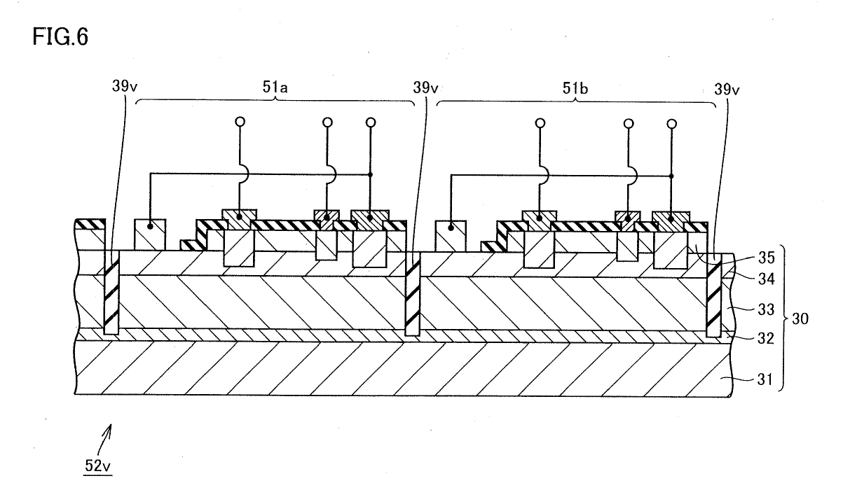

In addition, though regions R1 and R2 are electrically isolated from each other by groove portion 39 in the present embodiment, as shown in a power module (silicon carbide semiconductor device) 52v in FIG. 6, regions R1 and R2 may electrically be isolated from each other by an insulator portion 39v. Insulator portion 39v can be formed, for example, by burying an insulator in a groove or implanting an impurity causing a silicon carbide semiconductor to lose conductivity into epitaxial substrate 30.

### Fourth Embodiment

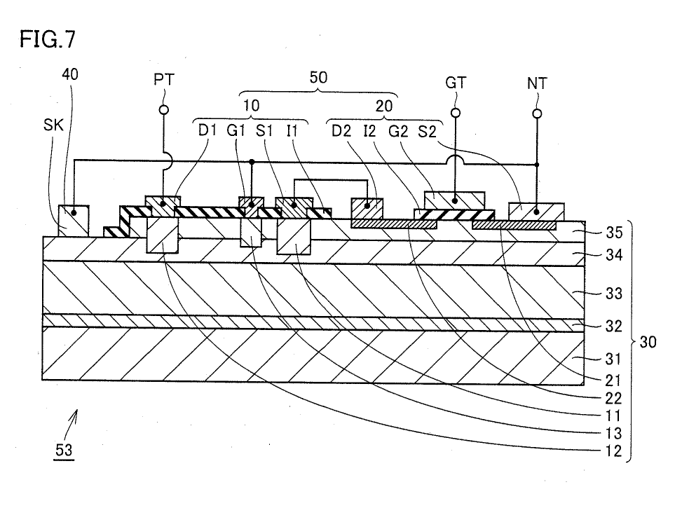

As shown in FIG. 7, a power module (silicon carbide semiconductor device) 53 in the present embodiment has epitaxial substrate (a silicon carbide substrate) 30, first electrode S1, second electrode D1, third electrode G1, a fourth electrode S2, a fifth electrode D2, a sixth electrode G2, interlayer insulating film I1, a gate oxide film I2 (gate insulating film), and Schottky electrode SK.

Epitaxial substrate 30 is made of SiC, and it has single crystal substrate 31, buffer layer 32, n layer (first layer) 34, upper p layer (second layer) 35, and lower p layer (third layer) 33. N layer 34 has the n type (the first conductivity type). Each of lower p layer 33 and upper p layer 35 has the p type (the second conductivity type different from the first conductivity type). Buffer layer 32 is provided on single crystal substrate 31. Lower p layer 33 is provided on buffer layer 32. N layer 34 is provided on lower p layer 33. Upper p layer 35 is provided on n layer 34 such that a part of n layer 34 is exposed. Therefore, in a direction of thickness, upper p layer 35 and lower p layer 33 sandwich n layer 34.

Epitaxial substrate 30 has first impurity region 11, second impurity region 12, third impurity region 13, a fourth impurity region 21, and a fifth impurity region 22. Each of first, second, fourth, and fifth impurity regions 11, 12, 21, and 22 has the n type, and third impurity region 13 has the p type. Each of first to third impurity regions 11 to 13 penetrates upper p layer 35 and reaches n layer 34, and third impurity region 13 is arranged between first and second impurity regions 11, 12. Each of fourth and fifth impurity regions 21, 22 is provided in upper p layer 35. Each of first impurity region 11, second impurity region 12, third impurity region 13, fourth impurity region 21, and fifth impurity region 22 is provided in the upper surface (one surface) of epitaxial substrate 30.

First to fifth electrodes S1, D1, G1, S2, D2 are provided on first to fifth impurity regions 11, 12, 13, 21, 22, respectively. First and fifth electrodes S1, D2 are electrically connected to each other and third and fourth electrodes G1, S2 are electrically connected to each other. Preferably, each of first to fifth electrodes S1, D1, G1, S2, D2 is an ohmic electrode.

Gate oxide film I2 covers a portion between fourth and fifth impurity regions 21, 22, on upper p layer 35. Sixth electrode G2 is provided on gate oxide film I2.

Interlayer insulating film I1 is provided on the upper surface of epitaxial substrate 30 and it has an opening through which each of first to third electrodes S1, D1, G1 passes. Thus, each of first electrode S1 and second electrode D1 is provided on epitaxial substrate 30 within the opening in interlayer insulating film I1. Interlayer insulating film I1 covers a side surface (a left side surface in FIG. 7) of upper p layer 35, which faces Schottky electrode SK. Preferably, a material for gate oxide film I2 is the same as a material for interlayer insulating film I1. More preferably, a thickness of gate oxide film I2 is the same as a thickness of interlayer insulating film I1

Schottky electrode SK is provided on the aforementioned part of n layer 34. Schottky electrode SK is electrically connected to fourth electrode S2.

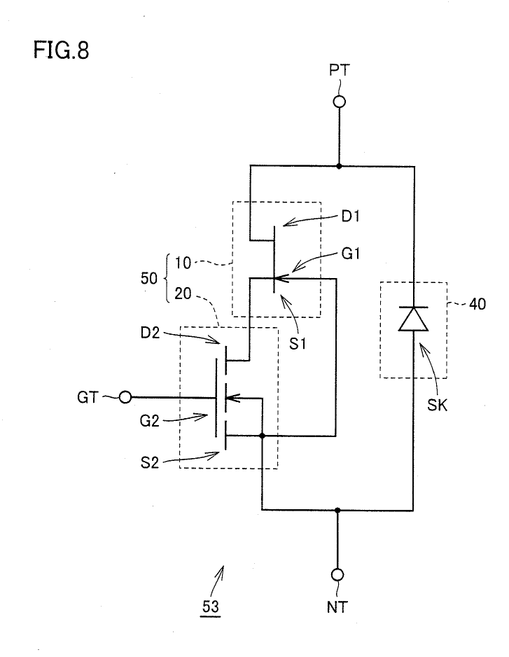

An equivalent circuit (FIG. 8) of power module 53 has a pair of main terminals NT and PT and control terminal GT for external connection, and has JFET portion 10, a MOSFET portion 20, and diode portion 40 as its internal structure. Specifically, sixth electrode G2 corresponds to control terminal GT. In addition, fourth electrode S2 corresponds to main terminal NT. Moreover, second electrode D1 corresponds to main terminal PT. Further, Schottky electrode SK corresponds to the anode of diode portion 40 and n layer 34 in contact with Schottky electrode SK in the vicinity of second electrode D1 corresponds to the cathode of diode portion 40.

First electrode S1, second electrode D1, and third electrode G1 correspond to the source, the drain, and the gate of JFET portion 10, respectively. In addition, fourth electrode S2, fifth electrode D2, and sixth electrode G2 correspond to the source, the drain, and the gate of MOSFET portion 20, respectively.

JFET portion 10 and MOSFET portion 20 as a whole function as single switching element 50 having the source, the drain, and the gate. Specifically, sixth electrode G2 corresponds to the gate. In addition, a portion where third electrode G1 and fourth electrode S2 are electrically connected to each other corresponds to the source. Moreover, second electrode D1 corresponds to the drain. Electrical connection between first and fifth electrodes S1, D2 corresponds to electrical connection between the source of JFET portion 10 and the drain of MOSFET portion 20. Further, electrical connection between third and fourth electrodes G1, S2 corresponds to electrical connection between the gate of JFET portion 10 and the source of MOSFET portion 20.

Namely, JFET portion 10 and MOSFET portion 20 cascode-connected to each other implement element 50 having three terminals of main terminals NT and PT and control terminal GT. According to this configuration, power module 53 can switch between main terminals NT and PT as a result of application of a voltage to control terminal GT. Specifically, in a case of an n channel, by setting a potential of control terminal GT to a positive potential not lower than a threshold value, an ON state between main terminals NT and PT can be established. Alternatively, for example, by setting a potential of control terminal GT to be lower than a threshold value (for example, a ground potential), an OFF state between main terminals NT and PT can be established.

Electrical connection between fourth electrode S2 and Schottky electrode SK corresponds to connection of main terminal NT to the anode of diode portion 40. In addition, contact of n layer 34 with Schottky electrode SK in the vicinity of second electrode D1 corresponds to connection of main terminal PT to the cathode of diode portion 40. Namely, diode portion 40 is connected to switching element 50 having JFET portion 10 and MOSFET portion 20, so as to function as a free-wheeling diode.

A method of manufacturing power module 53 will now be described.

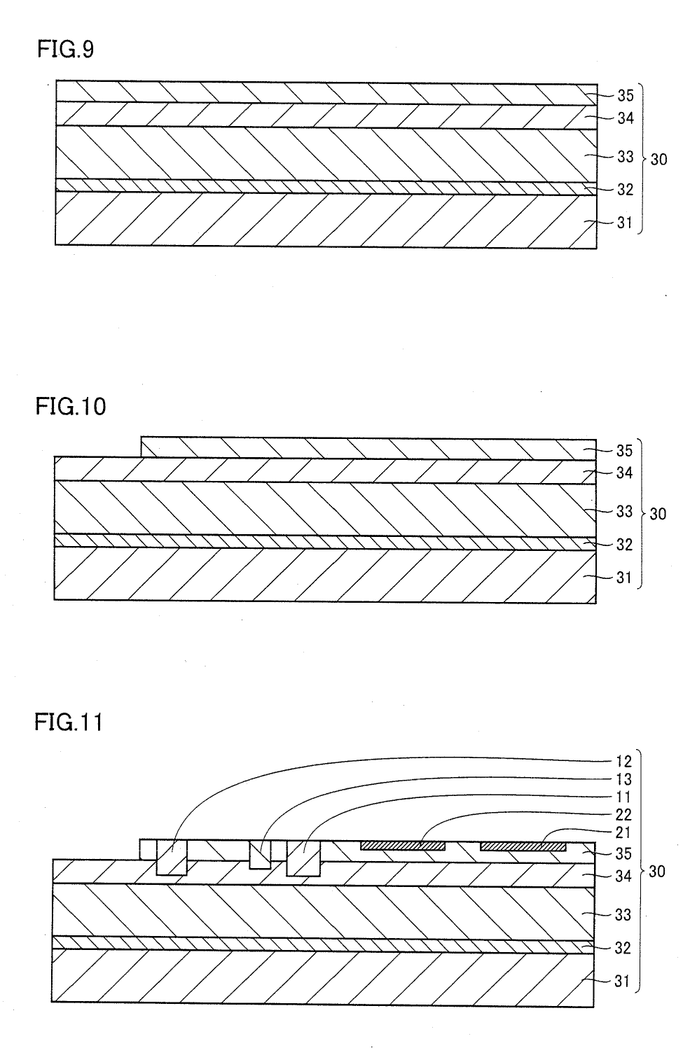

As shown in FIG. 9, epitaxial substrate 30 is formed. Specifically, buffer layer 32, lower p layer 33, n layer 34, and upper p layer 35 are formed on single crystal substrate 31 in this order through epitaxial growth. Epitaxial growth can be achieved, for example, with CVD (Chemical Vapor Deposition).

As shown in FIG. 10, a part of upper p layer 35 is removed from n layer 34. Thus, n layer 34 is exposed at a part of the upper surface of epitaxial substrate 30.

As shown in FIG. 11, first to fifth impurity regions 11, 12, 13, 21, and 22 are formed as impurity regions, in a portion of the upper surface of epitaxial substrate 30 where upper p layer 35 remains. An impurity region can be formed, for example, through ion implantation.

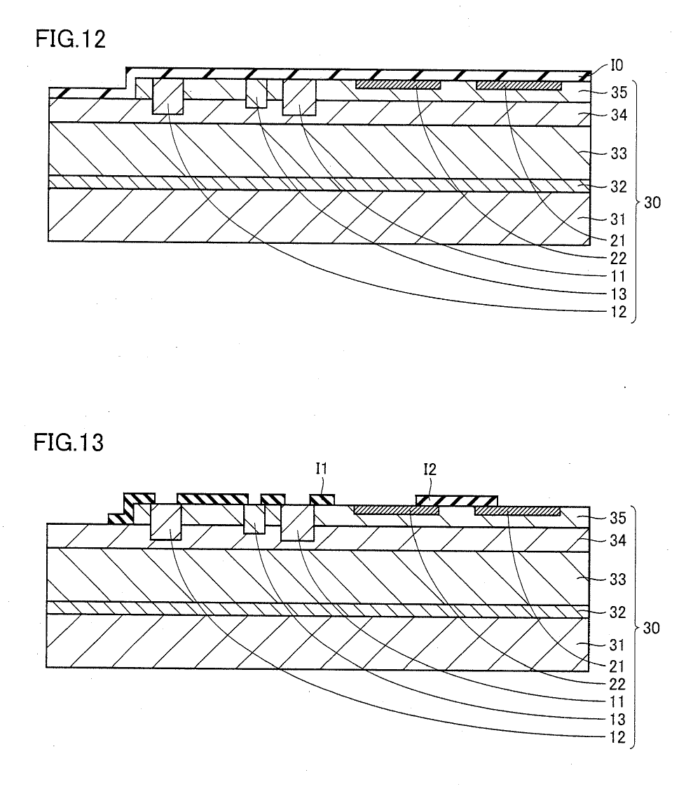

As shown in FIG. 12, an insulating film I0 is formed on the upper surface of epitaxial substrate 30. Insulating film I0 can be formed, for example, through thermal oxidation.

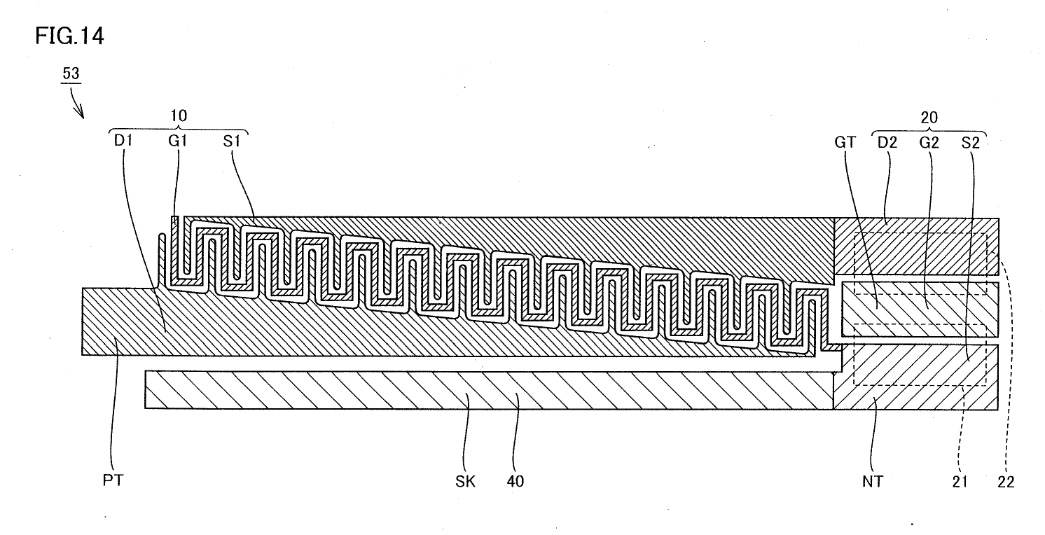

As shown in FIG. 13, insulating film I0 above is patterned, so that interlayer insulating film I1 and gate oxide film I2 are formed from insulating film I0. Patterning can be carried out, for example, with photolithography.

As shown in FIG. 7, electrodes are formed on the upper surface of epitaxial substrate 30. Specifically, first to fifth electrodes S1, D1, G1, S2, and D2 are formed as ohmic electrodes. In addition, sixth electrode G2 is formed on gate oxide film I2. Further, Schottky electrode SK is formed.

An interconnection structure for electrically connecting third electrode G1, fourth electrode S2, and Schottky electrode SK to one another is provided. In addition, an interconnection structure for electrically connecting first electrode S1 and fifth electrode D2 to each other is provided.

Power module 53 is obtained as above.

Since the configuration other than the above is substantially the same as the configuration in any of the first to third embodiments described above, the same or corresponding elements have the same reference characters allotted and description thereof will not be repeated.

According to power module 53 in the present embodiment, conduction between main terminal NT, which is implemented by third and fourth electrodes G1, S2 and Schottky electrode SK, and main terminal PT, which is implemented by second electrode D1, can be switched by a potential of control terminal GT, which is implemented by the sixth electrode. This switching operation has both of an advantage of a junction transistor and an advantage of an insulated gate transistor as a result of coordinated channel control making use of a depletion layer of a pn junction formed by n layer 34 and third impurity region 13 and channel control making use of sixth electrode G2 serving as an insulated gate on upper p layer 35. Specifically, similarly to the junction transistor, a high-speed operation is enabled and an ON resistance is low. In addition, similarly to the insulated gate transistor, a normally-off characteristic can readily be obtained. Further, a power module having such a structure that a diode is connected as a free-wheeling diode between a source and a drain of a switching element can be obtained with the use of a single epitaxial substrate 30.

### Fifth Embodiment

In the present embodiment, a two-dimensional layout of first to sixth electrodes S1, D1, G1, S2, D2, and G2 and Schottky electrode SK will particularly be described.

As shown in FIG. 14, main terminals NT, PT and control terminal GT correspond to fourth electrode S2, second electrode D1, and sixth electrode G2, respectively.

In the plan view (FIG. 14), first electrode S1 and fifth electrode D2 are integrated with each other on epitaxial substrate 30. Thus, first electrode S1 and fifth electrode D2 can electrically be connected to each other without particularly providing an interconnection structure.

In addition, third electrode G1 and fourth electrode S2 are integrated with each other on epitaxial substrate 30. Thus, third electrode G1 and fourth electrode S2 can electrically be connected to each other without particularly providing an interconnection structure.

Further, Schottky electrode SK is in contact with fourth electrode S2. Thus, Schottky electrode SK and fourth electrode S2 can electrically be connected to each other without particularly providing an interconnection structure.

Since the configuration other than the above is substantially the same as the configuration in the fourth embodiment described above, the same or corresponding elements have the same reference characters allotted and description thereof will not be repeated.

### Sixth Embodiment

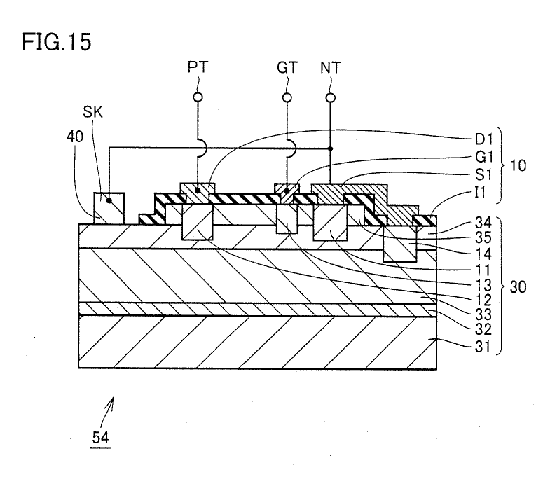

As shown in FIG. 15, in a power module (silicon carbide semiconductor device) 54 in the present embodiment, epitaxial substrate 30 has a sixth impurity region 14. Sixth impurity region 14 penetrates exposed n layer 34 and reaches lower p layer 33, and has the p type. In addition, first electrode S1 is electrically connected to sixth impurity region 14 and in contact with sixth impurity region 14 in the present embodiment. According to this configuration, first electrode S1 and lower p layer 33 are electrically connected to each other through the p-type sixth impurity region.

According to the present embodiment, since lower p layer 33 is set to a potential as high as first electrode S1, electric field concentration within n layer 34 can be relaxed.

Since the configuration other than the above is substantially the same as the configuration in the first to fifth embodiments described above, the same or corresponding elements have the same reference characters allotted and description thereof will not be repeated.

Though an epitaxial substrate is employed as a silicon carbide substrate in each embodiment above, a silicon carbide substrate other than an epitaxial substrate may be employed. In addition, a member for supporting a silicon carbide substrate may further be provided in a silicon carbide semiconductor device, and this member may be made of a material other than silicon carbide. From a point of view of mobility, the n type is desirably defined as the first conductivity type, however, the p type may be employed.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide semiconductor device, comprising:
a silicon carbide substrate including a first layer having a first conductivity type and a second layer provided on said first layer such that a part of said first layer is exposed and having a second conductivity type different from said first conductivity type, said silicon carbide substrate having first to third impurity regions penetrating said second layer and reaching said first layer, each of said first and second impurity regions having said first conductivity type, and said third impurity region being arranged between said first and second impurity regions and having said second conductivity type;
first to third electrodes provided on said first to third impurity regions, respectively; and
a Schottky electrode provided on the part of said first layer and electrically connected to said first electrode.

2. The silicon carbide semiconductor device according to claim 1, wherein
said first conductivity type is an n type.

3. The silicon carbide semiconductor device according to claim 1, wherein
each of said first to third electrodes is an ohmic electrode.

4. The silicon carbide semiconductor device according to claim 1, wherein
said silicon carbide substrate includes a third layer sandwiching said first layer between said second layer and the third layer, having said second conductivity type, and electrically connected to said first electrode.

5. The silicon carbide semiconductor device according to claim 1, wherein
said Schottky electrode is in contact with said first electrode.

6. The silicon carbide semiconductor device according to claim 1, wherein
said first layer has a first region in which said first to third impurity regions, said first to third electrodes, and said Schottky electrode are provided, and a second region electrically isolated from said first region.

7. A silicon carbide semiconductor device, comprising:
a silicon carbide substrate including a first layer having a first conductivity type and a second layer provided on said first layer such that a part of said first layer is exposed and having a second conductivity type different from said first conductivity type, said silicon carbide substrate having first to fifth impurity regions, each of said first, second, fourth, and fifth impurity regions having said first conductivity type and said third impurity region having said second conductivity type, each of said first to third impurity regions penetrating said second layer and reaching said first layer, said third impurity region being arranged between said first and second impurity regions, and each of said fourth and fifth impurity regions being provided on said second layer;
first to fifth electrodes provided on said first to fifth impurity regions, respectively, said first and fifth electrodes being electrically connected to each other, and said third and fourth electrodes being electrically connected to each other;
a gate insulating film covering a portion between said fourth and fifth impurity regions, on said second layer;
a sixth electrode provided on said gate insulating film; and
a Schottky electrode provided on the part of said first layer and electrically connected to said fourth electrode.
